(19) United States
(12) Patent Application Publication
(10) Pub. No.: US 2024/0157472 A1
(43) Pub. Date: May 16, 2024

(54) WAFER PROCESSING APPARATUS AND WAFER DICING METHOD

(71) Applicant: Samsung Electronics Co., Ltd., Suwon-si (KR)

(72) Inventors: Youngchul KWON, Suwon-si (KR); Goonwoo KIM, Suwon-si (KR)

(73) Assignee: Samsung Electronics Co., Ltd., Suwon-si (KR)

(21) Appl. No.: 18/507,459

(22) Filed: Nov. 13, 2023

(30) Foreign Application Priority Data
Nov. 16, 2022 (KR) 10-2022-0154017

(51) Int. Cl. B23K 26/0622; B23K 26/53; H01L 21/67

(52) U.S. Cl. CPC B23K 26/0622; B23K 26/53; H01L 21/67092; B23K 2101/40

(57) ABSTRACT

Provided is a wafer processing apparatus including a laser source for generating a laser beam including a plurality of pulses, a wafer support configured to support a wafer, and a beam transmission optical system for transferring the laser beam output from the laser source to the wafer, wherein the laser source sets parameters of the laser beam so that the laser beam is collected inside the wafer by a self-condensing phenomenon while moving along the inside of the wafer.

### CROSS-REFERENCE TO RELATED APPLICATION

This application is based on and claims priority under 35 U.S.C. § 119 to Korean Patent Application No. 10-2022-0154017, filed on Nov. 16, 2022, in the Korean Intellectual Property Office, the disclosure of which is incorporated by reference herein in its entirety.

### BACKGROUND

The inventive concepts relate to a wafer processing apparatus and a semiconductor device manufacturing method using the wafer processing apparatus, and more specifically, to a wafer processing apparatus configured to perform a stealth dicing process and a semiconductor device manufacturing method using the same.

A laser processing process refers to a process in which a laser beam is scanned on a surface of a workpiece to process the shape and/or physical properties of the surface of the workpiece. The laser processing process may include, for example, a patterning process forming a pattern on the surface of a workpiece, a process of modifying physical properties of the workpiece, such as wafer annealing, a forming process of changing the shape of the workpiece through heat melting, a cutting process of cutting the workpiece into multiple units through heat melting, and/or the like.

The cutting process using a laser beam includes a wafer dicing process, and the wafer is cut by irradiating, onto the workpiece, laser light in a wavelength band with a high absorption rate and heating and melting the workpiece. As an example of a wafer dicing process, a stealth dicing process in which an internal crack is induced by focusing a laser beam inside a wafer is used.

### SUMMARY

The inventive concepts provide a wafer processing apparatus and a wafer dicing method for improving yield.

Furthermore, the inventive concepts are not limited to the tasks described above, and other tasks may be clearly understood by one of ordinary skill in the art from the following description.

In order to achieve the technical tasks, the inventive concepts provide a wafer processing apparatus and a wafer dicing method as follows. According to an aspect of the inventive concepts, there is provided a wafer processing apparatus including a laser source configured to generate and output a laser beam, the laser beam including a plurality of pulses, a wafer support configured to support a wafer, and a beam transmission optical system configured to transfer the laser beam output from the laser source to the wafer, wherein parameters of the laser source are set such that the laser beam is collected inside the wafer by a self-condensing phenomenon while inside of the wafer.

According to another aspect of the inventive concepts, there is provided a wafer processing apparatus including a laser source configured to output a laser beam, the laser beam including a plurality of pulses, and a beam transmission optical system configured to transmit the laser beam output from the laser source to the wafer, wherein the laser beam transmitted to the wafer is configured to be concentrated in the wafer by a self-condensing phenomenon while passing through the inside of the wafer, and the wafer processing apparatus does not include a focusing lens optical system focusing the laser beam inside a wafer or a height sensor measuring a height from the wafer to the focusing lens optical system.

In order to achieve the technical tasks, the inventive concepts provide a wafer dicing method as follows.

According to another aspect of the inventive concepts, there is provided a wafer dicing method including preparing the wafer such that the wafer includes a plurality of device formation regions and a scribe lane region defining the plurality of device formation regions, repeatedly irradiating a laser beam along the scribe lane region such that a plurality of internal cracks form in the wafer, the laser beam having a pulse width in a range of 100 picoseconds (ps) to 100 nanoseconds (ns) and a diameter in a range of 10 micrometers (μm) to 30 μm, and separating the wafer along the plurality of internal cracks.

### BRIEF DESCRIPTION OF THE DRAWINGS

Embodiments of the inventive concepts will be more clearly understood from the following detailed description taken in conjunction with the accompanying drawings in which:

FIG. 1 is a block diagram illustrating a wafer processing apparatus according to some embodiments;

FIG. 2 is a schematic diagram for describing a wafer processing apparatus according to some embodiments;

FIG. 3 is a graph schematically illustrating a profile of a laser beam of the wafer processing apparatus of FIG. 1;

FIG. 4 is a schematic diagram for describing a wafer processing apparatus in which a wafer dicing process is performed according to some embodiments;

FIGS. 5A and 5B are graphs illustrating effects of a wafer processing apparatus according to some embodiments;

FIG. 6 is a flowchart illustrating a method of manufacturing a semiconductor device, according to some embodiments; and

FIGS. 7A to 7C are schematic diagrams for explaining a method of manufacturing a semiconductor device, according to some embodiments.

### DETAILED DESCRIPTION OF THE EMBODIMENTS

Hereinafter, embodiments of the inventive concepts will be described in detail with reference to the accompanying drawings. The same reference numerals are used for the same components in the drawings, and redundant descriptions thereof will be omitted.

When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

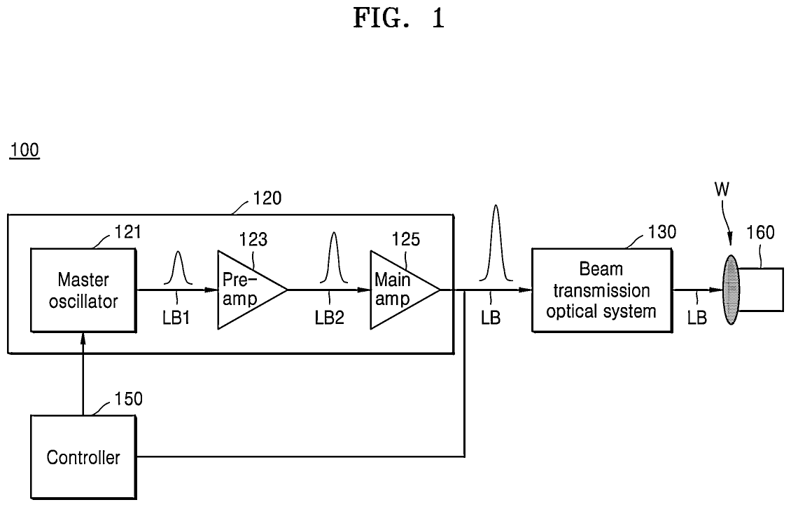

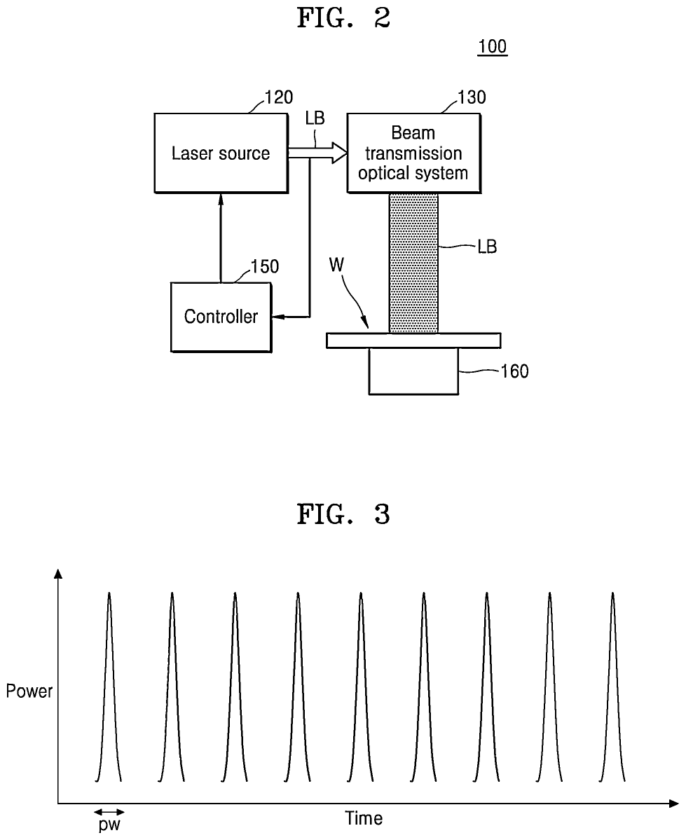

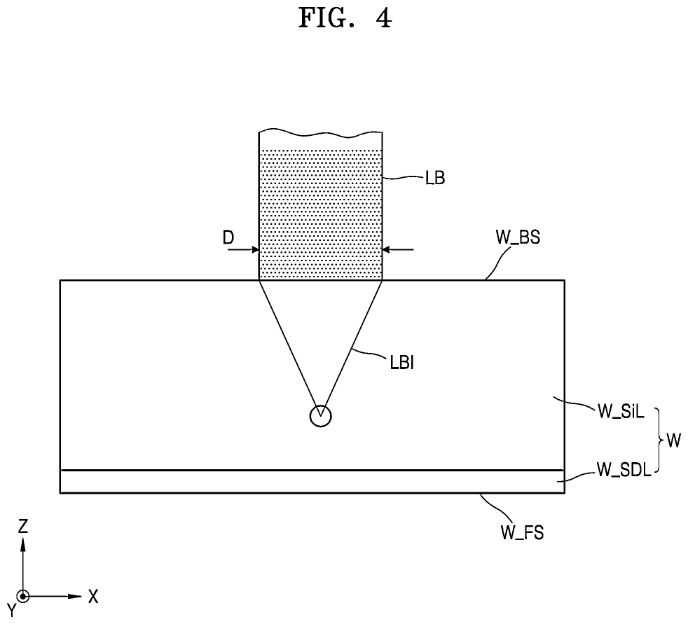

FIG. 1 is a block diagram illustrating a wafer processing apparatus 100 according to some embodiments. FIG. 2 is a schematic diagram for describing a wafer processing apparatus according to some embodiments. FIG. 3 is a graph schematically illustrating a profile of a laser beam of the wafer processing apparatus of FIG. 1. FIG. 4 is a schematic diagram for describing a wafer processing apparatus in which a wafer dicing process is performed according to some embodiments.

Referring to FIGS. 1 to 4, the wafer processing apparatus 100 may include a laser source 120, a beam transmission optical system 130, a controller 150, and a wafer support 160.

The wafer processing apparatus 100 may perform a stealth dicing process. Stealth dicing is a process of separating, with high precision and high speed, a wafer on which a semiconductor device is formed. For example, the stealth dicing may be a technique for focusing a laser beam LB of a wavelength band (e.g., a wavelength band having a low absorption rate for the wafer W) selected to transmit through the wafer W onto a place or point inside the wafer W through the surface of the wafer W.

In the stealth dicing technique, the laser beam LB may be repeatedly irradiated with pulses that last for a very short time, and may be focused onto a narrow area on the wafer W. For example, the laser beam LB may have a high peak power density spatially (through focusing) and temporarily (through pulsing) near a focal point set inside the wafer W. The laser beam LB with high peak power density causes a nonlinear absorption effect on the wafer W near the focal point, so that the laser beam LB may be absorbed at a high absorption rate near the focal point inside the wafer W than at the surface of the wafer W. Therefore, the laser beam may generate a high density defect (e.g., potential) by phase-shifting the portion of absorbing the laser beam LB in the wafer W, and facilitate vertical cracking of the wafer W.

In some embodiments, the laser source 120 may be an optical fiber laser, such as a master oscillator and power amplifier (MOPA) laser. For example, the laser source 120 may include a master oscillator 121, a pre-amplifier 123, and a main amplifier 125, which are coupled to each other with an optical fiber. However, the embodiments are not limited thereto, and the laser source 120 may be a MOPA laser composed of a solid bulk laser and a bulk amplifier, a MOPA laser composed of a tunable external cavity diode laser and a semiconductor light amplifier, and/or the like.

In some embodiments, the master oscillator 121 may include an optical fiber laser doped with at least one of ytterbium (Yb), erbium (Er), thulium (Tm), holmium (Ho), and/or the like. In some embodiments, the master oscillator 121 may generate a first laser beam LB1 having a wavelength of about 0.8 μm to about 1.4 μm. In some embodiments, the first laser beam LB1, the second laser beam LB2, and the laser beam LB may have a wavelength of about 1064 μm.

In some embodiments, the master oscillator 121 may operate in a Q switching scheme. The laser source 120 may generate the first laser beam LB1 with a pulse frequency of several hundred kHz. However, the embodiments are not limited thereto, and in some embodiments, the master oscillator 121 may operate in a mode-locking manner.

The master oscillator 121 may include a seed laser diode, an optical fiber including a gain medium, and a set of mirrors (e.g., a first mirror and a second mirror) facing each other to resonate the first laser beam. The seed laser diode may be a diode that generates a laser using forward semiconductor bonding as an active medium. When current is supplied to the seed laser diode, light may be emitted by an inversion between the density of a high energy level and the density of a low energy level and/or by the recombination of charge carriers in semiconductor bonding.

Light emitted from the seed laser diode may be used as pumping energy for an optical fiber including a gain medium. When a plurality of seed laser diodes are configured, a pump-signal coupling device may be provided between the plurality of seed laser diodes and the optical fiber. The pump-signal coupling device may combine optical signals output from the plurality of seed laser diodes into one and transmit the combined optical signal to an optical fiber including a gain medium.

Most of the light emitted spontaneously or inductively from the gain medium of the optical fiber may be weak in directivity. The first mirror and the second mirror reflect light emitted from the gain medium back to the gain medium, so that resonance in which induced emission of the gain material is repeated may occur. Some of the light repeatedly reflected between the first mirror and the second mirror may pass through the second mirror and output as the first laser beam LB1. The first laser beam LB1 may be coherent light.

The master oscillator 121 may further include an optical modulator for adjusting an intensity-time profile of the first laser beam LB1. The optical modulator may include an aperture configured to pass or shield the first laser beam LB1, and may adjust the intensity-time profile of the pulse of the first laser beam LB1 by adjusting the transmittance of the first laser beam LB1 passing through the aperture.

According to some embodiments, the master oscillator 121 may adjust a pulse width of the first laser beam LB1. The master oscillator 121 may further include a pulse width adjusting device for adjusting a pulse width of the first laser beam LB1. For example, according to at least some embodiments, the pulse width adjusting device may be configured to modulate the pulse width of the first laser beam LB1. The pulse width adjusting device may be, for example, at least one of an electro-optic modulator (EOM), an acousto-optic modulator (AOM), and/or the like.

According to some embodiments, the pulse width adjusting device may be and/or include, e.g., the acousto-optic modulator (AOM). According to some embodiments, the pulse width adjusting device may adjust the pulse width pw of the first laser beam LB1 based on the acoustic-optical modulator. In these cases, the pulse width adjusting device may finely adjust the pulse width pw of the first laser beam LB1 through a radio frequency (RF) signal.

According to some embodiments, the pulse width adjusting device may include a diffraction grating. The pulse width adjusting device may adjust the pulse width pw of the laser beam LB by combining a diffraction grating and a spatial optical modulator included in the beam transmission optical system 130. In these cases, the pulse width may be adjusted by projecting the time characteristics of the pulses of light provided through the diffraction grating onto the spatial region.

According to some embodiments, the pulse width adjusting device may include a multi-pulse generator. The multi-pulse generator may be configured to divide, delay, and/or recombine the laser beam LB received from the laser source 120. The pulse width adjusting device divides the laser beam LB into multiple optical paths through a multi-pulse generator, provides differential delay to each optical path, and then adjusts the pulse width pw of the laser beam while recombining the laser beams LB.

The pre-amplifier 123 may include a first pump laser diode, and the main amplifier 125 may include a second pump laser diode. In some embodiments, a plurality of first pump laser diodes included in the pre-amplifier 123 may be provided. In some embodiments, a plurality of second pump laser diodes included in the main amplifier 125 may be provided.

The pre-amplifier 123 may amplify the first laser beam LB1 to output the second laser beam LB2. According to some embodiments, the second laser beam LB2 may have the same wavelength as the first laser beam LB1. The main amplifier 125 may amplify the second laser beam LB2 to output the laser beam LB. According to some embodiments, the laser beam LB may have the same wavelength as the second laser beam LB2.

The first laser beam LB1, the second laser beam LB2, and the laser beam LB may have the same intensity-time profile by adjusting amplification ratios. For example, the first laser beam LB1, the second laser beam LB2, and the laser beam LB may have substantially the same pulse width, kurtosis, and/or skewness. However, the embodiments are not limited thereto, and at least one of the first laser beam LB1 and/or the second laser beam LB2 may have a pulse width, kurtosis, and skewness different from those of the laser beam LB.

The first pump laser diode included in the pre-amplifier 123 may generate a first pump laser beam. The second pump laser diode included in the main amplifier 125 may generate a second pump laser beam. The first pump laser beam may join the optical path of the first laser beam LB1 by a light coupler, and the second pump laser beam may join the optical path of the second laser beam LB2 by a light coupler. The first pump laser diode and the second pump laser diode may be driven by RF power.

In some embodiments, the first pump laser beam and the second pump laser beam may have different wavelengths from the wavelength of the first laser beam LB1. In some embodiments, the first pump laser beam and the second pump laser beam may have shorter wavelengths than the first laser beam LB1. In some embodiments, the first pump laser beam and the second pump laser beam may have a wavelength having a higher absorption rate for optical fibers than the laser beam LB. In these cases, as the first pump laser beam is absorbed by the optical fiber, the first laser beam LB1 may be amplified to output the second laser beam LB2. As the second pump laser beam is absorbed by the optical fiber, the second laser beam LB2 may be amplified to output the laser beam LB. However, the embodiments are not limited thereto, and the first pump laser beam and the second pump laser beam may have the same wavelength as the first laser beam LB1.

In some embodiments, isolators may be provided between the master oscillator 121 and the pre-amplifier 123 and/or between the pre-amplifier 123 and the main amplifier 125, respectively. For example, the isolator is also referred to as an optical diode and is an optical component that allows light to be transmitted in only one direction. The isolator may prevent the reverse progression of the first laser beam LB1 and the second laser beam LB2.

In some embodiments, an additional pre-amplifier may be further provided between the pre-amplifier 123 and the main amplifier 125, for example, depending on the intensity of the laser beam LB finally to be output from the laser source 120. For example, the laser source 120 may include two or more pre-amplifiers. An isolator and a collimator may be provided at an output end at which the laser beam LB is output from the laser source 120.

In some embodiments, as illustrated in FIG. 3, the intensity-time profile (hereinafter, simply, a time profile) of a single pulse included in the first laser beam LB1, the second laser beam LB2, and the laser beam LB (hereinafter, simply, a single pulse) may have a Gaussian distribution. For example, in some embodiments, the time profile of the single pulse may be symmetrical with respect to the center of the pulse. Here, the center of the pulse means a center point between a start point and an end point of the pulse. However, the embodiments are not limited thereto, and the time profile of the single pulse may be different from the Gaussian distribution.

The laser beam LB output from the laser source 120 may be transmitted to a wafer back surface W_BS by the beam transmission optical system 130. For example, the wafer processing apparatus 100 according to the technical idea of the inventive concepts may not include a lens optical system for focusing the laser beam LB. Accordingly, the laser beam LB output from the laser source 120 may be irradiated onto the wafer W in the form of a collimated beam.

The wafer W may be arranged on the wafer support 160 such that a wafer front surface W_FS faces the wafer support 160. The wafer W may include a device layer W_SDL adjacent to the wafer front surface W_FS and a silicon layer W_SiL adjacent to the wafer back surface W_BS.

According to some embodiments, the transmission laser beam LBI may concentrate in the silicon layer W_SiL by a self-condensing phenomenon, and in this case, a position where the transmission laser beam LBI concentrates may be a point in place which is positioned toward the silicon layer W_SiL by about 78 μm to about 100 μm from a surface where the device layer W_SDL and the silicon layer W_SiL meet.

The wafer support 160 may support the wafer W while the wafer W is being processed. The wafer support 160 may move the wafer W in a horizontal direction so that the laser beams LB are focused on different horizontal portions inside the wafer W. Accordingly, the wafer W is scanned along the scribe lane defined in the wafer W, and cracks may be formed in different portions inside the wafer W.

The beam transmission optical system 130 may include an attenuator, a wave-plate, and a spatial optical modulator. The attenuator may be an electronic device that reduces signal strength without distorting a waveform. The wave-plate may be an optical device that changes a polarization state of light passing through the wave-plate. The spatial optical modulator is a device that modulates light according to a position, and may adjust the diameter D of the laser beam LB output from the laser source 120. According to some-embodiments, the beam transmission optical system 130 may adjust the diameter D of the output laser beam LB to about 20 μm. For example, the beam transmission optical system 130 may include a beam expander, configured to reduce and/or enlarge the diameter D the laser beam to about 20 μm. However, the embodiments are not limited thereto, and the beam transmission optical system 130 may adjust the diameter D of the output laser beam LB to be greater or less than about 20 μm.

As shown in FIG. 4, the transmission laser beam LBI may concentrate inside the wafer W through a self-condensing phenomenon, which is a nonlinear optical phenomenon, while passing through the back surface of the wafer W. For example, in the cases wherein the laser beam LB has a Gaussian distribution, the intensity of light at the center is strong, and the intensity of light may decrease toward the outer portion from the center. In these cases, due to the nonlinear optical phenomenon, the refractive index of the medium may be increased at the center portion with strong light intensity, and the refractive index of the medium may be relatively low at the outer portion. Accordingly, the transmission laser beam LBI at the center portion may have a relatively slow speed, and the laser beam LB at the outer portion may move at a relatively high speed. Eventually, due to the difference in the speed between the center portion and the outer portion, light concentration phenomenon may occur as the transmission laser beam LBI moves toward the inside of the vertical direction Z of the wafer W.

In order for the self-condensing phenomenon to occur, the peak power of the laser beam LB irradiated toward the wafer W may be equal to or greater than a predetermined (or otherwise determined) value. According to some embodiments, in order for the transmission laser beam LBI to concentrate inside the wafer W through a self-condensing phenomenon, a laser beam LB having peak power of about 31.1 kilowatts (kW) or more, which is critical peak power of silicon, may be required. In addition, the self-condensing phenomenon may occur in proportion to the peak power density obtained by dividing the peak power by a unit area of the laser beam LB.

According to some embodiments, the peak power may be proportional to the pulse width pw of the laser beam and the power P of the laser beam, and may be inversely proportional to the pulse frequency.

In order to increase the peak power of the laser beam LB irradiated toward the wafer W more than the critical peak power of silicon, the pulse width pw or the power P of the laser beam LB may be adjusted, and in order to adjust the peak power density, the diameter D of the laser beam LB may be adjusted. For example, by adjusting certain parameters of the laser beam LB irradiated toward the wafer W, the transmission laser beam LBI may concentrate in the wafer W through a self-condensing phenomenon.

According to embodiments, the power P of the laser beam may be in a range of about 30 Watt to about 70 Watt. The range of the power P of the laser beam may be a power range of the laser beam that may be easily output, and in this case, the self-condensing phenomenon of the transmission laser beam LBI may be induced by adjusting the pulse width pw of the laser beam LB and/or the diameter D of the laser beam LB. For example, the wafer processing apparatus 100 according to the technical idea of the inventive concepts may induce the self-condensing phenomenon of the transmission laser beam LBI by adjusting the pulse width pw or/and the diameter D of the laser beam LB within the power range adjacent to the power P, thereby performing the dicing process of the wafer W.

In some embodiments, the pulse width pw of the laser beam LB provided to the wafer back surface W_BS through the beam transmission optical system 130 in the wafer processing apparatus 100 according to the technical idea of the inventive concepts may be in a range of about 100 picoseconds (ps) to about 100 nanoseconds (ns), and the diameter D of the laser beam LB may be in a range of about 10 micrometers (μm) to about 30 μm.

When the pulse width pw and the diameter D of the laser beam LB are within the above ranges, respectively, the transmission laser beam LBI transmitted into the wafer W through the wafer back surface W_BS may concentrate inside the wafer through a self-condensing phenomenon. For example, when the pulse width pw and the diameter D of the laser beam LB are within the above ranges, respectively, the peak power of the laser beam LB may be about 31.1 kilowatts (kW or more, which is the critical peak power of silicon.

The controller 150 may generate a signal for controlling the laser source 120. The controller 150 may generate signals for controlling parameters of the laser beam LB generated by the laser source 120. According to embodiments, the controller 150 may control the pulse width pw, the diameter D, and the power of the laser beam LB generated from the laser source 120.

According to some embodiments, the controller 150 may measure the pulse width pw (and/or receive measurement data) of the laser beam LB generated from the laser source 120 and then control the pulse width pw of the laser beam LB so that the peak power of the laser beam LB by the pulse width pw is stable within about 3%. For example, the controller 150 may stabilize the laser beam LB by automatically adjusting the parameters of the laser beam LB.

Here, the controller 150 may be implemented by hardware, firmware, software, or any combination thereof. For example, the controller 150 may be a computing device, such as a workstation computer, a desktop computer, a laptop computer, a tablet computer, and/or the like; and/or the controller 150 may be a simple controller, a microprocessor, a complex processor such as a central processing unit (CPU), a graphics processing unit (GPU), and/or the like, a processor configured by software, or dedicated hardware or firmware. The controller 150 may be implemented by, for example, a general-purpose computer or application-specific hardware such as a digital signal processor (DSP), a field programmable gate array (FPGA), an application specific integrated circuit (ASIC), and/or the like.

In some embodiments, the operation of the controller 150 may be implemented as instructions stored on a machine-readable medium that may be read and executed by one or more processors. Here, the machine-readable medium may include any mechanism for storing and/or transmitting information in a form readable by a machine (e.g., a computing device). For example, machine-readable media may include read only memory (ROM), random access memory (RAM), magnetic disk storage media, optical storage media, flash memory devices, electrical, optical, acoustic, or other forms of radio signals (e.g., carrier, infrared, digital signals, etc.), and any other signals.

Firmware, software, routines, and instructions may be configured to perform the operation described for controller 150 or any process described below.

Eventually, the wafer processing apparatus 100 according to the technical idea of the inventive concepts may allow the laser beam LB provided to the wafer W in the form of a collimate beam to concentrate in the wafer W by a self-condensing phenomenon while moving along the inside of the wafer W. Therefore, a focusing lens optical system that focuses the laser beam LB, e.g., before being provided to the wafer W, is unnecessary, and a height sensor that measures the vertical (Z) height from the wafer back surface W_BS to the focusing lens optical system is unnecessary to increase the accuracy of the focusing lens optical system.

For example, a comparative wafer processing apparatus including a focusing lens optical system needs to maintain a constant distance between the lens and the wafer in order to concentrate the laser beam at the intended height. To this end, a height sensor that measures the height of the focusing lens optical system is essentially required. However, depending on the optical characteristics of the wafer back surface W_BS, the height measurement function may be locally incomplete, inconsistent, and/or an error may occur. For example, there may be a problem that errors are caused by insufficient reflected light quantities of the height sensor by, e.g., an outer skirt aluminum penetrating the back surface during the pattern process of the wafer front surface W_FS. Due to the error of the height sensor, the position where the laser beam concentrates in the wafer is uneven, and as a result, the yield of the semiconductor device degrades.

However, the wafer processing apparatus 100 according to the technical idea of the inventive concepts does not require the focusing lens optical system and the height sensor because the laser beam concentrates into the wafer W through the self-condensing phenomenon of the transmission laser beam LBI. Accordingly, an error caused by the height sensor is fundamentally blocked, and ultimately, the yield of the semiconductor device may be improved.

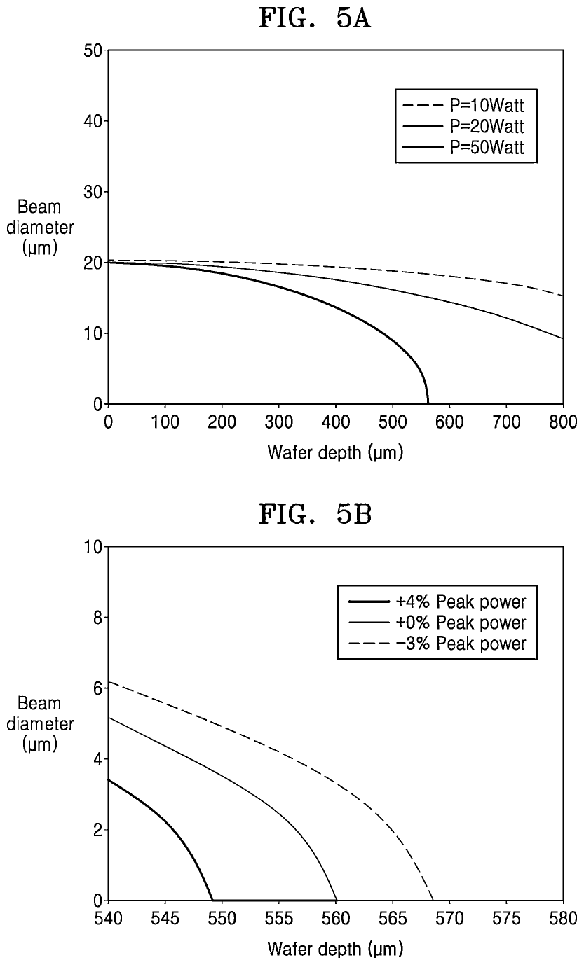

FIGS. 5A and 5B are graphs illustrating effects of a wafer processing apparatus according to some embodiments.

Referring to FIGS. 4 and 5A, when the diameter D of the laser beam LB is about 20 μm and the power P of the laser beam is 50 Watts, the thick solid line indicates a position where the transmission laser beam concentrates. When the diameter D of the laser beam LB is about m and the power P of the laser beam is about 20 Watts, the thin solid line indicates a position where the transmission laser beam concentrates. When the diameter D of the laser beam LB is about 20 μm and the power P of the laser beam is about 10 Watts, the broken line indicates a position where the transmission laser beam concentrates.

For example, when the diameter D of the laser beam LB is set to be around 20 μm, the transmission laser beam LBI may concentrate into the silicon layer W_SiL of the wafer W even when the power P of the laser beam is about 50 Watts. Here, the horizontal axis of the graph, the wafer depth, may represent a distance from the wafer back surface W_BS to a position where the laser beam concentrates. As illustrated, when the average thickness of the silicon layer is in a range of about 640 μm to about 760 μm and the diameter D of the laser beam LB is about 20 μm and the power P of the laser beam is about 50 Watts, the transmission laser beam LBI may concentrate at a point in place proceeding toward the silicon layer W_SiL by a self-condensing phenomenon by about 78 μm to about 100 μm from a surface where the device layer W_SDL and the silicon layer W_SiL meet.

Referring to FIGS. 4 and 5B, the thin solid line indicates positions where the laser beam having a target peak power concentrates in a wafer W, the thick solid line indicates positions where the laser beam LB having peak power greater by about 4% than the target peak power concentrates inside the wafer W, and the broken line indicates positions where the laser beam LB having peak power less by about 3% than the target peak power concentrates inside the wafer W.

As a result, a position where the laser beam LB having peak power greater by about 4% than the target peak power concentrates in the wafer W has a difference of about 10 μm or more than a reference light concentration position, and a position where the laser beam LB having peak power greater by about 3% than the target peak power concentrates in the wafer W has a difference of about 10 μm or more than the reference light concentration position, and thus, the peak power of the laser beam LB should have stability within about 3% in order to secure the stability of the dicing process.

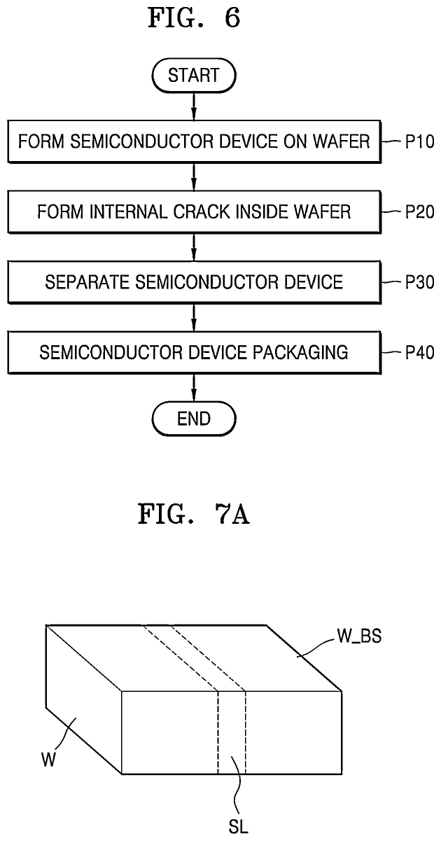

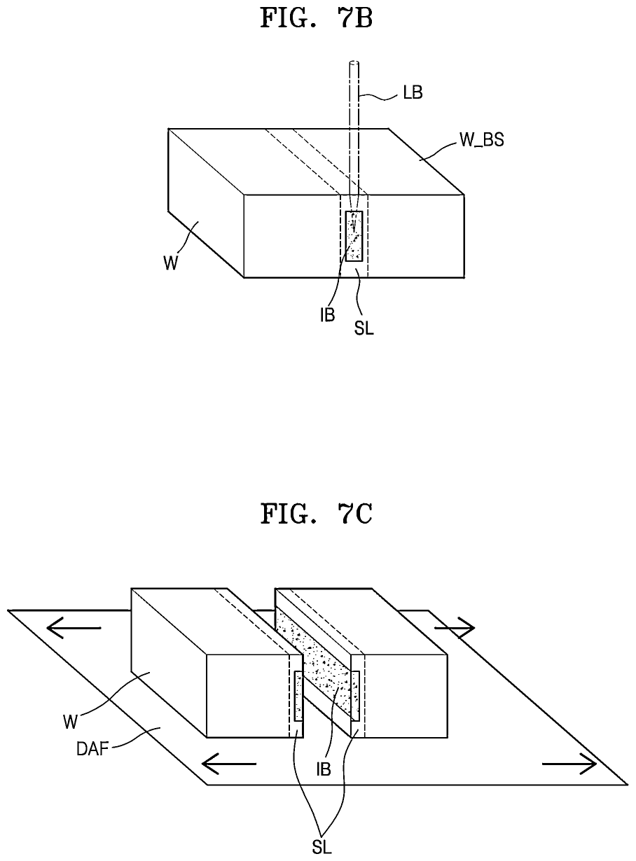

FIG. 6 is a flowchart illustrating a method of manufacturing a semiconductor device, according to embodiments. FIGS. 7A to 7C are schematic diagrams for explaining a method of manufacturing a semiconductor device, according to some embodiments.

Referring to FIGS. 6 and 7A, in operation P10, a semiconductor device may be formed on the wafer W. The wafer W may include device forming regions on which a semiconductor device is formed and a scribe lane SL separating the device forming regions.

The wafer W may include, for example, a semiconductor element and/or a compound semiconductor. For example, the wafer W may include a semiconductor element, such as silicon (Si) and/or germanium (Ge), or a compound semiconductor, such as silicon carbide (SiC), gallium arsenide (GaAs), indium arsenide (InAs), and indium phosphide (InP).

In some embodiments, the wafer W may have a silicon on insulator (SOI) structure. The wafer W may include a buried oxide layer formed on the front surface of the wafer W. In some embodiments, the wafer W may include a conductive region formed on the front surface of the wafer W, for example, a well doped with impurities. In some embodiments, the wafer W may have various device separation structures, such as shallow trench isolation (STI) that separates the doped wells from each other. Although not shown, a plurality of material layers may be formed on the wafer front surface W_FS. At least one material layer may be formed on the wafer back surface W_BS.

The semiconductor device formed in the wafer W may be a memory device and/or a non-memory device. In some embodiments, the memory device may be a nonvolatile NAND-type flash memory. In some embodiments, the memory device may include phase-change random access memory (PRAM), magnetoresistive RAM (MRAM), resistive RAM (ReRAM), ferroelectric RAM (FRAM), NOR flash memory, and/or the like. In addition, the memory device may be a volatile memory device in which data is lost when power is cut off, such as dynamic random access memory (DRAM) and/or static RAM (SRAM). In some embodiments, the memory device may be a logic chip, a measuring device, a communication device, a digital signal processor (DSP), a system-on-chip (SOC), and/or the like.

The process of forming the semiconductor device may include: i) an oxidation process of forming an oxide film; ii) a lithography process including spin coating, exposure, and development; iii) a thin film deposition process; iv) a dry or wet etching process; v) a metal wiring process; and/or the like.

The oxidation process is a process of forming a thin and uniform silicon oxide film by chemically reacting oxygen or water vapor with a surface of a silicon substrate at a high temperature of about 800° C. to about 1200° C. The oxidation process may include dry oxidation and wet oxidation. The dry oxidation may react with oxygen gas to form an oxide film, and the wet oxidation may react oxygen with water vapor to form an oxide film.

In some embodiments, an SOI structure may be formed on the substrate by an oxidation process. The substrate may include a buried oxide layer. In some embodiments, the substrate may have various device isolation structures, such as STI.

The lithography process is a process of transferring a circuit pattern previously formed on a lithography mask to a substrate through exposure. The lithography process may be performed in the order of spin coating, exposure, and development processes.

The thin film deposition process may be, for example, any one of atomic layer deposition (ALD), chemical vapor deposition (CVD), plasma-enhanced CVD (PECVD), metal organic CVD (MOCVD), physical vapor deposition (PVD), reactive pulsed laser deposition, molecular beam epitaxy, and DC magnetron sputtering.

The dry etching process may be, for example, any one of reactive ion etching (RIE), deep RIE (DRIE), ion beam etching (IBE), and argon (Ar) milling. As another example, the dry etching process that may be performed on the wafer W may be atomic layer etching (ALE). In addition, the wet etching process that may be performed on the wafer W may be an etching process using, as an etchant gas, such as at least one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂, and/or COS.

The metal wiring process may be a process of forming a conductive wiring (metal wire) to implement a circuit pattern for operating a semiconductor device. Through the metal wiring process, ground, power, and signal transmission paths for operating the semiconductor devices may be formed. The metal wiring may include gold, platinum, silver, aluminum, tungsten, and the like.

In some embodiments, in a semiconductor device formation process, a planarization process, such as a chemical mechanical polishing (CMP) process, an ion implantation process, and the like may be performed.

Referring to FIGS. 6 and 7B, in operation P20, an internal crack IB may be formed in the wafer W.

The internal crack of the wafer W may be formed by the laser beam LB output by the wafer processing apparatus 100 of FIG. 1. For example, the laser beam LB may be irradiated toward the wafer back surface W_BS. The laser beam LB irradiated toward the wafer back surface W_BS may condense to a point through a self-condensing phenomenon inside the wafer W. The laser beam LB concentrated at one point may form cracks up and down at the one point while melting the wafer by applying heat to the inside of the wafer W.

In some embodiments, a pre-grinding process may be performed on the wafer back surface W_BS to reduce the thickness of the wafer W before forming an internal crack of the wafer W.

Referring to FIGS. 6 and 7C, in operation P30, a semiconductor device may be separated. After the wafer W in which the internal crack IB is formed is attached to a die attach film (DAF), the DAF may be prolonged horizontally to separate the semiconductor devices. In some embodiments, a back grinding process of polishing the wafer back surface W_BS may be additionally performed before providing the die attach film DAF.

Referring to FIG. 6, the separated semiconductor devices may be packaged in operation P40. The packaging process may include a wire bonding process, a molding process, a marking process, a solder ball mounting process, and the like.

The embodiments have been disclosed in drawings and specifications as described above. Although some embodiments have been described using specific terms in the present specification, they are used only for the purpose of describing the technical idea of the present disclosure and are not used to limit the meaning or the scope of the present disclosure described in the claims. Therefore, it will be understood by those skilled in the art that various changes in form and details and equivalent other embodiments may be made therein without departing from the scope of the present inventive concepts. Accordingly, the true scope of protection of the inventive concepts should be determined by the technical idea of the appended claims.

While the inventive concepts have been particularly shown and described with reference to embodiments thereof, it will be understood that various changes in form and details may be made therein without departing from the spirit and scope of the following claims.

What is claimed is:

1. A wafer processing apparatus comprising:
a laser source configured to generate and output a laser beam, the laser beam including a plurality of pulses;
a wafer support configured to support a wafer; and
a beam transmission optical system configured to transfer the laser beam output from the laser source to the wafer,
wherein parameters of the laser source are set such that the laser beam is collected inside the wafer by a self-condensing phenomenon while inside of the wafer.

2. The wafer processing apparatus of claim 1, wherein the parameters include a pulse width of a plurality of pulses included in the laser beam, a diameter of the laser beam, and a power of the laser beam.

3. The wafer processing apparatus of claim 2, wherein the pulse width of the plurality of pulses included in the laser beam is in a range of 100 picoseconds (ps) to 100 nanoseconds (ns).

4. The wafer processing apparatus of claim 2, wherein the diameter of the laser beam is in a range of 10 micrometers (μm) to 30 μm.

5. The wafer processing apparatus of claim 1, wherein a pulse width of the plurality of pulses is in a range of 100 picoseconds (ps) to 100 nanoseconds (ns) and a diameter of the laser beam is in a range of 10 micrometer (μm) to 30 μm.

6. The wafer processing apparatus of claim 1, wherein a peak power of the laser beam provided from the laser source has stability within 3%.

7. The wafer processing apparatus of claim 6, further comprising:
a controller configured to control the laser source, wherein the controller is configured to stabilize the laser beam by controlling numerical values of the parameters of the laser beam generated by the laser source.

8. The wafer processing apparatus of claim 7, wherein
the laser source further comprises a pulse width adjusting device configured to adjust a pulse width of the laser beam, and
the controller is configured to control the pulse width adjustment device of the laser source based on a measured pulse width of the laser beam generated by the laser source.

9. The wafer processing apparatus of claim 1, wherein the laser source comprises:
a master oscillator configured to output a first laser beam;
a pre-amplifier configured to amplify the first laser beam to output a second laser beam; and
a main amplifier configured to amplify the second laser beam and output the laser beam.

10. The wafer processing apparatus of claim 1, wherein the parameters include a diameter of the laser beam, and the beam transmission optical system is configured to adjust the diameter of the laser beam transmitted from the laser source.

11. The wafer processing apparatus of claim 10, wherein the beam transmission optical system adjusts the diameter of the laser beam to be in a range of 10 micrometers (μm) to 30 μm.

12. A wafer processing apparatus configured to perform a stealth dicing process on a wafer, the wafer processing apparatus comprising:
a laser source configured to output a laser beam, the laser beam including a plurality of pulses; and
a beam transmission optical system configured to transmit the laser beam output from the laser source to the wafer,
wherein the laser beam transmitted to the wafer is configured to be concentrated in the wafer by a self-condensing phenomenon while passing through the inside of the wafer, and the wafer processing apparatus does not include a focusing lens optical system focusing the laser beam inside a wafer or a height sensor measuring a height from the wafer to the focusing lens optical system.

13. The wafer processing apparatus of claim 12, wherein a pulse width of the plurality of pulses included in the laser beam is in a range of 100 picoseconds (ps) to 100 nanoseconds (ns).

14. The wafer processing apparatus of claim 12, wherein a diameter of the laser beam is in a range of 10 micrometers (μm) to 30 μm.

15. The wafer processing apparatus of claim 12, wherein a pulse width of the plurality of pulses included in the laser beam is in a range of 100 picoseconds (ps) to 100 ns and a diameter of the laser beam is in a range of 10 micro (μm) to about 30 μm.

16. The wafer processing apparatus of claim 12, further comprising:
a controller configured to control the laser source, wherein the controller is configured to control at least one parameter of the laser beam generated by the laser source such that a peak power of the laser beam has stability within 3%.

17. The wafer processing apparatus of claim 16, wherein the at least one parameter controlled by the controller includes a pulse width of the laser beam generated by the laser source.

18. A wafer dicing method comprising:
preparing the wafer such that the wafer includes a plurality of device formation regions and a scribe lane region defining the plurality of device formation regions;
repeatedly irradiating a laser beam along the scribe lane region such that a plurality of internal cracks form in the wafer, the laser beam having a pulse width in a range of 100 picoseconds (ps) to 100 nanoseconds (ns) and a diameter in a range of 10 micrometers (μm) to 30 μm; and
separating the wafer along the plurality of internal cracks.

19. The wafer dicing method of claim 18, wherein a power of the laser beam is in a range of 30 Watts to 70 Watts.

20. The wafer dicing method of claim 18, further comprising:
grinding a back surface of the wafer before the plurality of internal cracks form in the wafer; and
grinding the back surface of the wafer after the plurality of internal cracks form in the wafer.
